(19) United States
(12) Patent Application Publication
(10) Pub. No.: US 2025/0181958 A1
(43) Pub. Date: Jun. 5, 2025

(54) SELF-STABILISATION OF A GKP CODE BY PARAMETRIC MODULATION IN A MICROWAVE FREQUENCY COMB

(71) Applicants: INSTITUT NATIONAL DE RECHERCHE EN INFORMATIQUE ET EN AUTOMATIQUE, Le Chesnay (FR); ASSOCIATION POUR LA RECHERCHE ET LE DÉVELOPPEMENT DES MÉTHODES ET PROCESSUS INDUSTRIELS-ARMINES, Paris (FR)

(72) Inventors: Philippe CAMPAGNE-IBARCQ, Le Chesnay (FR); Mazyar MIRRAHIMI, Le Chesnay (FR); Alain SARLETTE, Le Chesnay (FR); Pierre ROUCHON, Paris (FR)

(21) Appl. No.: 18/845,165

(22) PCT Filed: Mar. 9, 2023
(86) PCT No.: PCT/EP2023/056074

§ 371 Date: Sep. 9, 2024

(30) Foreign Application Priority Data
Mar. 10, 2022 (FR) 2202121

(51) Int. Cl. G06N 10/70; G06N 10/40; H03K 3/38; H10N 60/12

(52) U.S. Cl. CPC G06N 10/70; G06N 10/40; H03K 3/38; H10N 60/12

(57) ABSTRACT

A superconducting microwave quantum circuit includes a controllable-energy Josephson junction element connected to a linear passive circuit portion exhibiting a plurality of resonant modes, of which the Foster's first-form decomposition across the terminals of the Josephson junction element includes a target resonant mode exhibiting an impedance Z higher than 13 kohm and a pulsation w. The energy of the Josephson junction element is controllable and modulated by at least two respective pulse trains within which the pulses are separated by a duration 2π/w and have a width of less than one tenth of this duration, the amplitude of the pulses within each respective pulse train being modulated by a respective sinusoidal carrier and the pulse trains are respectively offset pairwise by a duration Δt such that |sin(w*At)| equals 13 kohm/Z, so that the resonant mode of pulsation w is stabilised in one of two GKP states encoding a qubit.

### CROSS-REFERENCE TO RELATED APPLICATIONS

This Application is a Section 371 National Stage Application of International Application No. PCT/EP2023/056074, filed Mar. 9, 2023, not in English, which claims priority to French Patent Application No. FR2202121, filed Mar. 10, 2022, the contents of which are incorporated herein by reference in their entireties.

### FIELD OF THE DISCLOSURE

The invention relates to the field of superconducting microwave resonator quantum circuits, and in particular implementing a quantum corrector code using a bosonic code.

### BACKGROUND OF THE DISCLOSURE

The production of a quantum computer is to date prevented by the noise modifying the state of the quantum bits (hereinafter qubits), causing logic errors. In spite of significant advances made over the last 20 years to limit the noise sources, the universal fault-tolerant quantum calculation is currently out of reach. Quantum error correction aims to solve this problem.

The type of logic error to be corrected has two natures: bit flip and phase flip. The main methodology used aims to encode a few logic qubits in a much vaster informational space. In this informational space, the qubits are encoded into states known as “coding”, which are chosen so that the noise does not make it possible to induce a direct transition from one coding state to another.

The noise, which thus induces transitions from a coding state to a non-coding state, may be detected and corrected to unambiguously bring the system back to the initial coding, that is to say that each non-coding state is associated with a single coding state. So as not to perturb the quantum information, this error detection and correction must take place without measuring the logic qubits.

The most widely used quantum error correction method is called “surface code”. This type of solution is implemented by the biggest names in the quantum sector, such as Google, IBM, Delft University, Zurich University, etc., and to date constitutes the most studied solution worldwide.

In a surface code, the quantum information is carried by a 2D network of two-level systems. Gates with one and two fault-tolerant qubits exist. The greatest drawback of this technology is that it requires a large number of very high quality two-level systems to be able to perform the calculation. In addition to the costs incurred by this architecture, this generates problems related to the need to control a large number of quantum systems.

The work of the Applicant has led her to consider that surface codes have disadvantages that require other solutions to be explored. For this reason, the Applicant studied bosonic codes.

Bosonic codes are a family of quantum error correction codes that are based on storing qubits in bosonic modes. These codes comprise three main sub-families: ‘cat’ codes, binomial codes, and GKP (Gottesman-Kitaev-Preskill) codes.

An example of cat codes are the Schrödinger two-legged cat codes implemented by Yale University, the Quantic team, or companies such as Quantum Computing Inc, Alice & Bob, or Amazon Web Services.

In these codes, the coding states are Schrödinger cat states. As opposed to the GKP code, only one of the two types of logic error can be eliminated. Therefore, it is necessary to concatenate this code into a repetition code to be able to manage the two types of logic error.

One advantage of these codes in relation to the GKP code is that the elimination of one of the two types of errors may be rendered arbitrarily good by simply varying the size of the cat. This is not possible with GKP codes, for which only the increase of the ratio between the dissipation rates induced by design (or rate of measurement and correction in the case of a measurement stabilisation) and the intrinsic dissipation of the resonator makes it possible to exponentially extend the lifetime of the logic qubit.

Another example are the Schrödinger cat codes with n>2 legs implemented by Yale University and Quantum Computing Inc. As opposed to Schrödinger 2-legged cat codes, the two types of logic error may be corrected. However, the elimination does not follow an exponential law but a polynomial law when the rate of detection and correction or the dissipation rate induced by design are increased.

Binomial codes have for their part problems similar to those of Schrödinger cat codes with n>2 legs. Moreover, they only protect against losses of photons, and not other types of noise such as pure phase shift.

GKP codes also have a plurality of implementations. A first example is a GKP code stabilised by Rabi interactions with an ancillary qubit implemented by Yale University in partnership with the Quantic team. This method induces logic errors, for example when the ancillary qubit undergoes an error type modifying its state according to the axis of the Bloch sphere corresponding to the operator present in the Rabi interaction during the interaction. It is possible to eliminate it by using an ancillary qubit of which one of the errors is eliminated (for example, a Schrödinger cat), but this method is complex to implement and to date not achieved experimentally.

Another example is a GKP code stabilised by modular operators. Proposals exist for implementing a Hamiltonian dynamic supported by modular operators that, combined with a dissipation with a single photon, stabilises the GKP code. The circuits proposed for implementing this dynamic are, however, not achievable. Indeed, either they involve an element known as “coherent phase-slip element”, or they involve a “high-impedance gyrator”, of which no implementation has yet been demonstrated to date.

Therefore, no corrector code works satisfactorily to date. For the most advanced, the point at which the logic qubits have a coherence/lifetime longer than the underlying physical systems has barely been reached, but has never been significantly exceeded.

### SUMMARY

The invention improves the situation. For this purpose, it proposes a superconducting microwave quantum circuit comprising a controllable-energy Josephson junction element connected to a linear passive circuit portion exhibiting a plurality of resonant modes, of which the Foster's first-form decomposition across the terminals of the Josephson junction element comprises a target resonant mode exhibiting an impedance Z higher than 13 kohm and a pulsation w. The energy of said Josephson junction element is controllable and modulated by at least two respective pulse trains within which the pulses are separated by a duration 2π/w and have a width of less than one tenth of said duration, the amplitude of the pulses within each respective pulse train being modulated by a respective sinusoidal carrier and the pulse trains being respectively offset pairwise by a duration Δt such that |sin(w*Δt)∥ equals 13 kohm/Z, so that the resonant mode of pulsation w is stabilised in one of two GKP states encoding a qubit.

This device is particularly advantageous because it makes it possible to implement modular operators for implementing a qubit in a GKP code, which may be reliably stabilised and making it possible to considerably improve the ratio between the coherence time and the gate time in relation to all of the qubits implemented up to now.

According to various embodiments, the invention may have one or more of the following features:
the pulsation wi of the sinusoidal carrier of each respective pulse train is zero, so that the GKP coding states are the lowest energy states in an interaction representation lowering the pulsation of the target resonant mode to a pulsation lower than a fifth of the amplitude of the effective modular potential generated for the target resonant mode divided by the reduced Planck constant, said lowest energy states being stabilised by coupling with an environment of which the product of the Boltzmann constant by the effective temperature is lower than the Josephson energy in this representation,
the pulsation wi of the sinusoidal carrier of each respective pulse train is a pulsation of a resonant mode of the Foster's decomposition across the terminals of the Josephson junction element of the linear passive circuit portion different from the pulsation w, the superconducting microwave quantum circuit further comprising a homodyne linear measurement member of the resonant modes corresponding to the respective pulsations wi, arranged to measure the displacements of the resonant modes of pulsation wi in a direction of their respective phase plane determined by the phase of the sinusoidal carrier of pulsation wi, and a feedback member arranged to displace the state of the target resonant mode in a direction of its phase plane determined by the phase of the pulse train corresponding to the pulsation wi in relation to the phase reference of said target resonant mode, proportionally to a measurement received from the measurement member,
the pulsation wi of the carrier of each respective pulse train is a pulsation of one of the resonant modes of the Foster's first-form decomposition across the terminals of the Josephson junction element of the linear passive circuit portion different from the pulsation w, the linear passive circuit portion being arranged so that said resonant modes of pulsation wi dissipate their respective excitations into an environment of which the product of the temperature by the Boltzmann constant is lower than the product of the pulsation wi by the reduced Planck constant and according to a rate higher than √(w/4*Zᵢ/(6.5 kohm))*eᵢ where Zi is the impedance of the mode of pulsation wi across the terminals of the elements of said Josephson junction element and ei is the average Josephson energy integrated over the duration of a pulse, each pulse being preceded by a pre-pulse and followed by a post-pulse, the pre-pulse and the post-pulse being modulated by a quadrature sinusoidal carrier with the carrier of the pulse and being offset in relation to the pulse of a respective duration δ lower than 1/(5w) and having an opposite amplitude and of absolute value lower than 1/(3δw),
the respective pulse trains are activated in time windows that overlap, and the pulsations of the sinusoidal carriers that modulate their respective amplitudes are distinct,
the respective pulse trains are activated one after another and are modulated by the same sinusoidal carrier of pulsation wi, so that a pulse train ends before the activation of the following train, each train comprising a number of pulses between 10 and 10\hat{ }8,
the Josephson junction element has a controllable phase making it possible to modify the position of the GKP state grid,
the impedance of the target resonant mode is adjustable, and the offset between the respective pulse trains may be adapted to make it possible to modify the shape of the mesh of the GKP state grid,
the impedance of the target resonant mode is equal to 13 kohm, the pulsation of the target resonant mode is modified in order to perform a rotation of π/2 of the GKP state grid, and the duration between the pulses within the same train is modified in a manner adapted to this modified pulsation,
the impedance of the target resonant mode is equal to 15 kohm, the pulsation of the target resonant mode is modified in order to perform a rotation of π/3 of the GKP state grid, and the duration between the pulses within the same train is modified in a manner adapted to this modified pulsation,
the circuit comprises two controllable-energy Josephson junction elements, each connected to said linear passive circuit portion such that the impedance of the target resonant mode exhibited at at least one of two Josephson junction elements is adjustable, the energy of each Josephson junction element being controllable and modulated depending on each respective impedance of the target resonant mode,
the circuit comprises two circuits of which one at least is as described previously interconnected so as to define a logic gate, and
the two circuits exhibit an adjustable impedance of the target resonant mode, the offset between the respective pulse trains being able to be adapted to make it possible to modify the shape of the mesh of the GKP state grid, and the linear passive circuit portion of each circuit being connected to the Josephson junction element of the other circuit by an adjustable coupler so as to control the impedance of the target resonant mode of each circuit exhibited at the Josephson junction element of the other circuit.

### BRIEF DESCRIPTION OF THE DRAWINGS

Other features and advantages of the invention will become more apparent upon reading the following description, taken by way of illustrative and non-limiting examples, taken from drawings wherein:

FIG. 1 is a representation of wave functions of the states of a GKP code,

FIG. 2 is a representation of a superconducting microwave resonator quantum circuit according to a first embodiment of the invention,

FIG. 3 represents the activation time profile of the Josephson junctions of FIG. 2 when the Foster's first-form decomposition across the terminals of the Josephson junction element comprises a target resonant mode exhibiting an impedance Z equal to 13 kohm,

FIG. 4 represents the displacements of the state of the target resonant mode of the circuit of FIG. 2 in a laboratory reference frame and in a rotating reference frame, when the Foster's first-form decomposition across the terminals of the Josephson junction element comprises a resonant mode exhibiting an impedance Z equal to 13 kohm,

FIG. 5 represents an alternative embodiment of FIG. 3 when the impedance Z is higher than 13 kohm,

FIG. 6 represents an alternative embodiment of FIG. 4 when the impedance Z is higher than 13 kohm,

FIG. 7 represents a so-called Hamiltonian implementation of the circuit of FIG. 2,

FIG. 8 represents the activation time profile of the Josephson junctions of FIG. 7,

FIG. 9 represents the effective potentials generated by means of the circuit of FIG. 7 in a rotating reference frame, as well as the probability density of the GKP coding states,

FIG. 10 represents the energy levels of the states of FIG. 9,

FIG. 11 represents a so-called feedback implementation of the circuit of FIG. 2,

FIG. 12 represents the displacements of the state of the GKP target resonant mode of the circuit of FIG. 11 by feedback,

FIG. 13 represents a so-called dissipative implementation of the circuit of FIG. 2,

FIG. 14 represents the activation time profile of the Josephson junctions of FIG. 13,

FIG. 15 represents the displacements of the state of the target resonant mode of the circuit of FIG. 11 by dissipation, and

FIG. 16 is an example of implementation of the circuit of FIG. 13.

The drawings and the following description mainly contain elements of certain character. Therefore, not only may they be used to better understand the present invention, but also to help to define it, if necessary.

### DETAILED DESCRIPTION OF ILLUSTRATIVE EMBODIMENTS

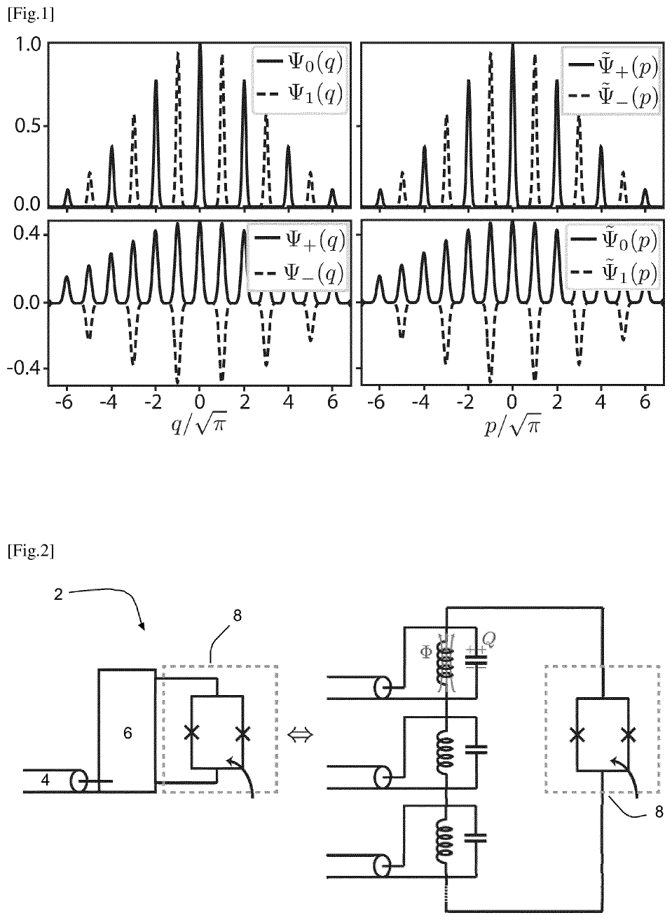

The invention relates to the implementation of logic qubits by way of GKP codes. In order to better understand how to stabilise the latter, FIG. 1 offers a representation of coding states “0” and “1” and of their symmetrical and asymmetrical superpositions “+” and “−” of a square GKP code according to the quadratures q and p. The GKP code makes it possible to ensure that orthogonal logic states have remote supports in the phase plane (q,p).

Alternatively, the mesh of the GKP grid may be a parallelogram, from the moment that its area in the plane (q,p) at the normalised coordinates (such as the commutator [q,p]=i) equals 4π. A particular case when the angle of the parallelogram equals π/3 is known as “hexagonal code”.

In the following, the equations presented are with reference to idealistic GKP codes, of which the states extend infinitely in the phase plane (infinitely squeezed states), hereinafter “infinite-size GKP codes”. The aim of the invention is an implementation with “realistic” GKP codes, that is to say of which the states have a support of finite-size in the phase plane (finitely squeezed states), hereinafter “finite-size GKP codes”. This implementation may involve minor changes to the equations presented hereinafter, and the modifications in the stabilisation protocol will be specified whenever possible below.

As can be seen in this figure, the various coding states are separated by V (x) according to the quadrature q or according to the quadrature p.

In this figure, each dial represents the probability distribution for certain pairs of orthogonal states in bit (0; 1) or in phase (+; −), according to the quadrature q or the quadrature p. The distance between the states 0 and 1 in q makes it possible to obtain a protection against the bit flips, whereas the distance between the states + and − in p makes it possible to obtain a protection against the phase flips. The circuits according to the invention make it possible to generate and stabilise these states by effective coupling with the target mode via the modular operators e^{±2i\sqrt{π}q} and e^{±2i\sqrt{π}p} that it implements, where q and p are the quadrature operators of the target mode in the rotating reference frame at the frequency of the target mode. These modular operators are the stabilisers of the infinite-size GKP code.

In a so-called Hamiltonian implementation, the invention raises the energy degeneration of the specific states of these stabilisers, and the coding states are of the lowest energy and therefore stabilised in the presence of dissipation to an effective low-temperature reservoir.

In a so-called measurement feedback implementation, these stabilisers are measured and the result of the measurement makes it possible to stabilise the coding states by feedback.

In a so-called engineering of the dissipation implementation, the interaction between the target mode and high-dissipation ancillary modes via the modular operators of the target mode on the one hand, and the linear operators of the ancillary modes on the other hand, generates a modular effective dissipation stabilising the GKP coding states.

In the case of main errors for the superconducting resonators, that is to say the dissipation with a single photon, the Applicant esteems that the qubits thus encoded may have a life in the order of magnitude of the tenth of a second, while remaining controllable by fault-tolerant gates and of a duration in the order of the microsecond, which represents an improvement of the ratio between the coherence time and the gate time of a plurality of order of magnitudes in relation to all of the qubits implemented up to now.

The Applicant discovered a class of quantum circuits that makes it possible to implement the modular operators mentioned above by combining a controllable-energy Josephson junction element and a linear passive circuit portion, by implementing a particular control of the energy of the Josephson junction element.

FIG. 2 represents a generic view of a quantum circuit of this type. As can be seen in this figure, the circuit 2 comprises a transmission line 4 connected to a terminal (or “port”) connected to a linear passive circuit portion 6, as well as a Josephson junction element 8 connected to the terminals of the linear passive circuit portion 6.

The transmission line 4 may be produced by any manner known in the sector, on chip or off chip, 2D or 3D, etc., according to any known geometry for a microwave transmission line.

The passive circuit portion 6 may be produced by any known manner making it possible to obtain the Foster's decompositions mentioned below when they carry a signal in the microwave range.

The Josephson junction element 8 has a controllable Josephson energy. As represented in FIGS. 2, 7, 11 and 13, the circuits represented make it possible to control the Josephson energy by applying a magnetic flux between two Josephson junctions forming a SQUID (Superconducting Quantum Interference Device), but may also be controlled by other methods (more complex multiple junction circuits, semi-conducting junction with a voltage bias).

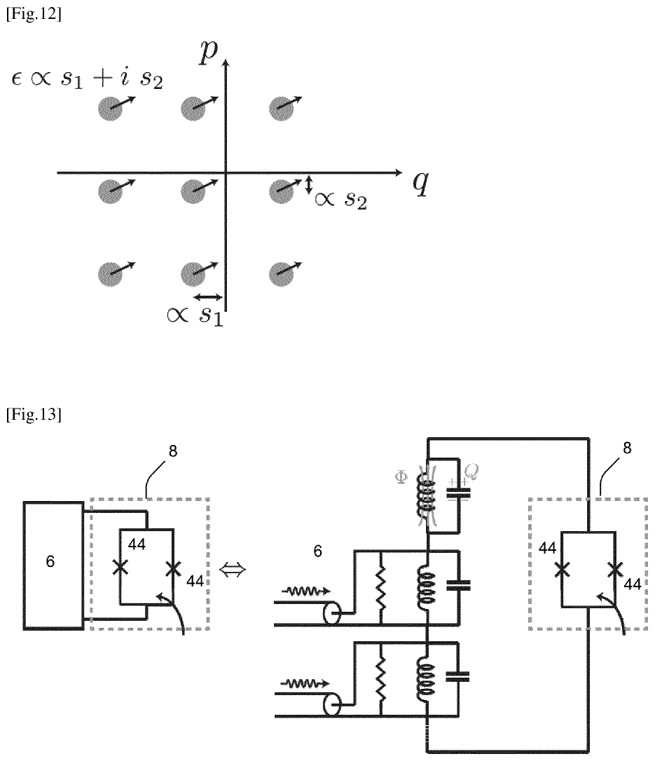

According to the embodiments, the circuit 2 may be modified and arranged in order to make it possible to stabilise the GKP code in a Hamiltonian implementation (FIGS. 7 to 10), a feedback implementation (FIGS. 11 and 12), or a dissipation implementation (FIGS. 13 to 16).

Generally, the invention is based on two principles.

The first principle is that the linear passive circuit portion 6 exhibits one or more resonant modes of which the Foster's first-form decomposition (see for example the article by Foster, R. M., “A reactance theorem”, Bell System Technical Journal, vol. 3, no. 2, pp. 259-267, November 1924) across the terminals of the Josephson junction element comprises a resonant mode exhibiting an impedance Z higher than or equal to 13 kohm. The equivalent circuit is represented on the right in FIG. 2. In the following, this resonant mode will also be called “target mode”.

The impedance value is particularly high because it corresponds to double the resistance quantum (which is defined by h/4e², i.e. 6.5 ohm), which makes it possible for the Josephson junction element 8 to implement, in the rotating reference frame of the target mode, at various times, two distinct modular operators and that switch, corresponding to the stabilisers of the GKP code. Indeed, the spatial pulsation n of the modular operator is connected to the impedance exhibited at the Josephson element via

η=\sqrt{2πZ/6.5 kohm}.

The product of the pulsations of the two modular operators equals 4π in the case of the square GKP code, and is greater for a non-square GKP code. The value of 13 kohm is therefore the minimum value for stabilising the GKP code. With impedance values above 19.5 kohm, it would be possible for example to stabilise qutrits.

The second principle is that the control of the Josephson energy, represented by the arrow that penetrates the Josephson junction element 8 in FIG. 2, makes it possible to organise the displacements that the states of the GKP code can perform as described below.

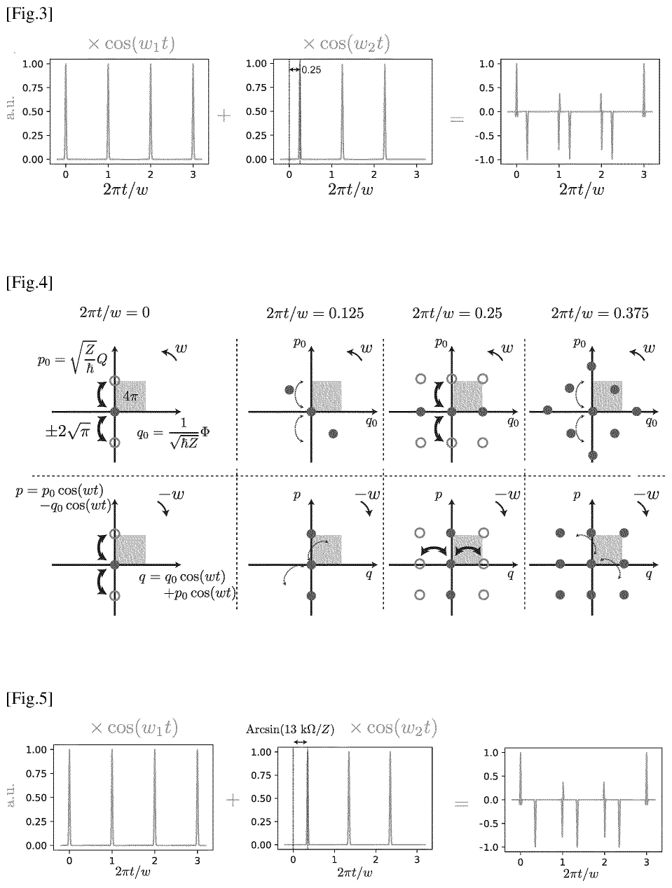

Thus, FIG. 3 represents the signals used to modulate the Josephson energy. This control, to the right of FIG. 3 is the resultant of the sum of two sinusoids of respective pulsation w1 and w2 that each modulate the amplitude of a pulse train, which trains are offset from one another by a quarter period associated with the pulsation of the resonant mode of which the impedance is equal to 13 kohm. Each pulse has a width smaller than a tenth of this quarter period.

Another way of describing FIG. 3 is that the signal for controlling the Josephson energy of the Josephson junction element 8 is the sum of two control signals that act to “switch off” or “switch on” the Josephson energy in a particular way at chosen moments:
The first control signal is such that the Josephson energy is activated at each period associated with the pulsation of the impedance resonant mode higher than or equal to 13 kohm, and substantially zero at other moments, and this energy is modulated in amplitude by a sinusoid of pulsation w1 equal to the pulsation of a first ancillary mode for correcting the conjugated operator q in the Foster's decomposition,
The second control signal is such that the resulting Josephson energy is activated at each period associated with the pulsation of the impedance resonant mode higher than or equal to 13 kohm, and substantially zero at other moments, and this energy is modulated in amplitude by a sinusoid of pulsation w2 equal to the pulsation of a second ancillary mode for correcting the conjugated operator p, and
the first control signal and the second control signal are offset from one another by a quarter period associated with the pulsation w of the target resonant mode of impedance equal to 13 kohm.

Alternatively, the control signals may be activated at each half-period instead of each period as mentioned above. If necessary, this may be done by inverting the sign of the pulse.

The result of this combination in the context of the GKP code implemented by the circuit 2 is represented with FIG. 4.

FIG. 4 represents the various possible displacements on the GKP grid depending on the moments, in the fixed reference frame of axes q0 and p0 (at the top) or in a rotating reference frame of axes q and p (at the bottom) with the pulsation w of the target mode. The notion of rotating reference frame is also called “interaction representation”, and the two expressions may be interchanged in the following.

In the fixed reference frame, due to the resonance of the mode of pulsation w, the states of the resonator will rotate with the pulsation w, and coherence and discreet displacements according to the mesh of the GKP grid will be possible every quarter period if the target mode is exhibited at the Josephson junction element with a suitable impedance. Yet, with the activation profile of FIG. 3, this only occurs every quarter period, according to one pulse train or the other. This means that when 2πt/w equals 0.125 or 0.375, the Josephson energy is zero, which prevents any displacement outside of the grid. Conversely, all of the quarter periods, this is possible, according to +q0, −q0, +p0 or −p0. It can also be clearly understood with the representation in the rotating reference frame, wherein the states are stable (since the reference frame rotates with the pulsation w), and the displacements rotate (therefore a displacement is possible according to +q, −q, +p or −p) and are possible every quarter period.

Thus, the circuit of FIG. 2 makes it possible to generate and stabilise a GKP grid state since the dynamic of the mode may be coherent and constrained according to the GKP grid.

In the particular case of FIGS. 3 and 4, the resonant mode of pulsation w exhibits an impedance equal to 13 kohm, so that the unitary operators q and p cover an area equal to 4π.

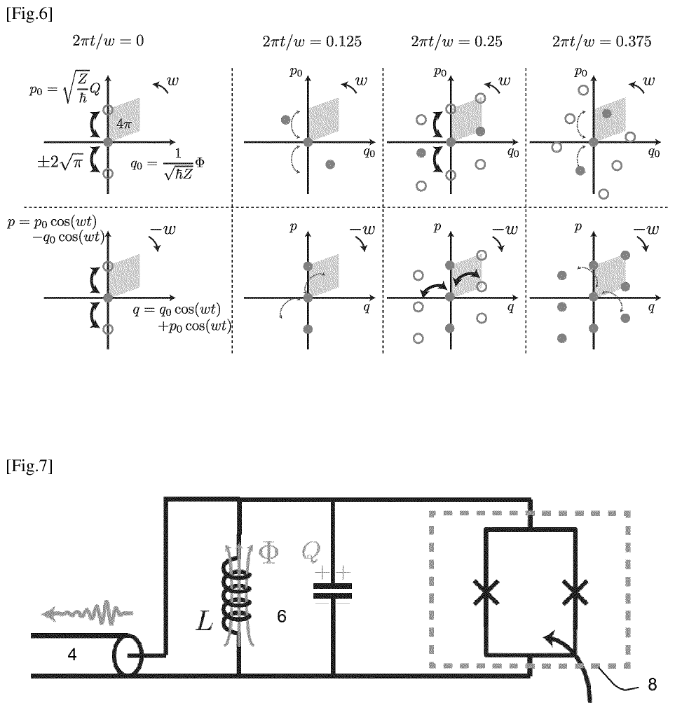

Nevertheless it is possible that the resonant mode of pulsation w exhibits an impedance higher than 13 kohm. In this case, as represented in FIGS. 5 and 6, the pulse trains should be slightly offset from one another, and the GKP grid is then a diamond-shape of which the area remains equal to 4π.

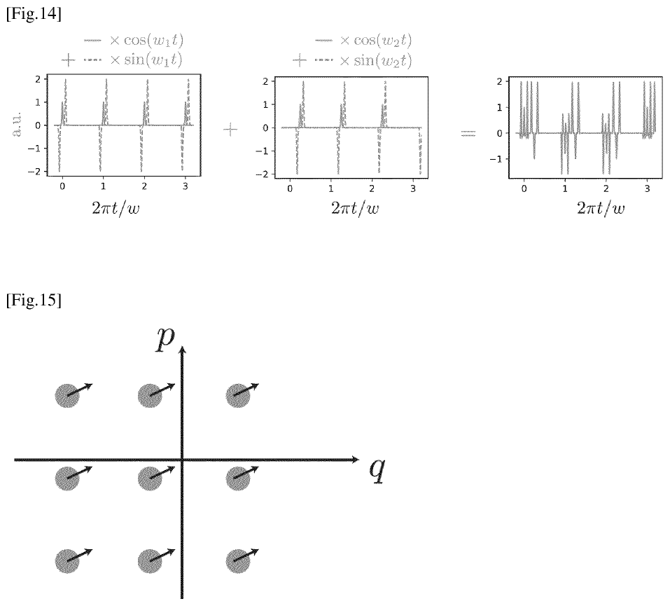

FIGS. 7 to 15 represent three distinct embodiments that make it possible to stabilise the qubit encoded in the GKP code of such a circuit. Thus, FIGS. 7 to 10 describe a quantum circuit implementing a Hamiltonian stabilisation and a modulation diagram of the Josephson junction element, FIGS. 11 and 12 describe a quantum circuit implementing feedback stabilisation, and FIGS. 14 to 16 describe a quantum circuit implementing a dissipation stabilisation.

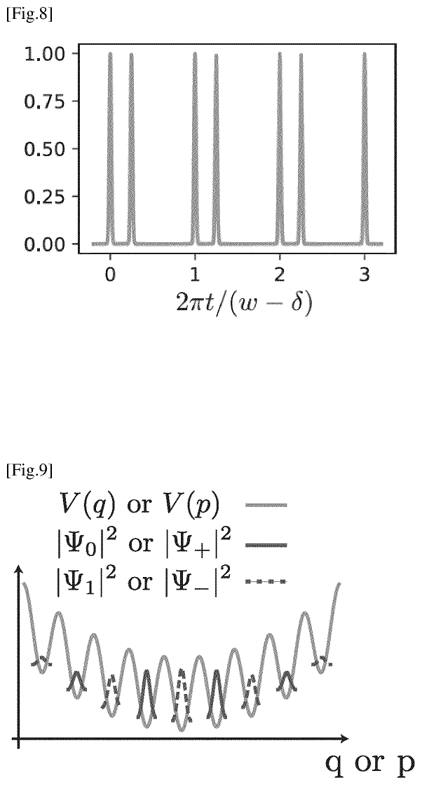

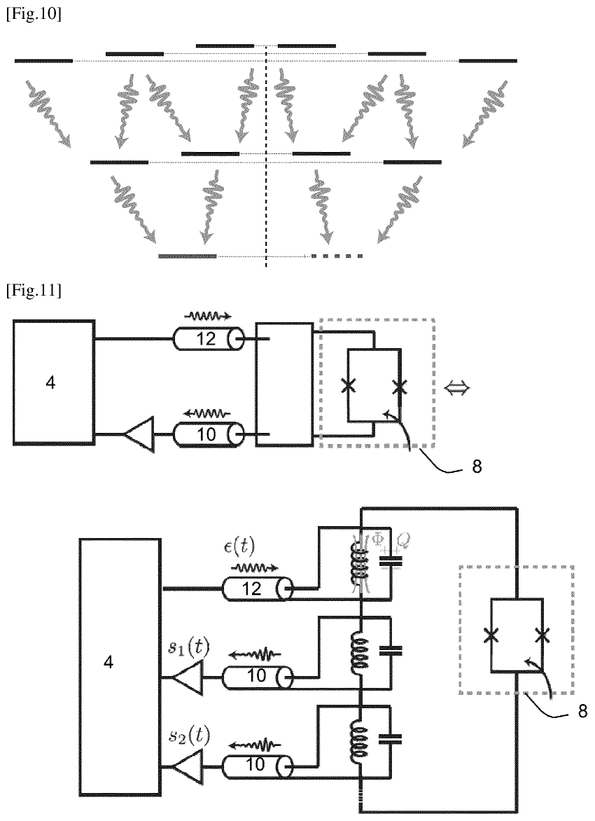

FIG. 7 shows the Foster's first-form decomposition of a linear passive circuit portion 6. In this embodiment, the pulsations w1 and w2 are zero, so that the activation profile of the Josephson energy of the Josephson junction element 8 is represented in FIG. 8, and induces energy potentials represented in FIG. 9 for the modes p and q. Thus, the pulse trains are each modulated by a sinusoid of zero pulsation that therefore still equals 1. In other words, it is reminded that the value 1 is a sinusoid of zero pulsation. Alternatively, the pulse trains could be doubled symmetrically in relation to the period.

In the rotating reference frame, and in the absence of Josephson dynamic, all of the states of the oscillator are degenerated and of zero energy. The sequence of pulses in this Hamiltonian implementation generates an egg box potential according to q and p that raises the degeneration of these energy levels and ensure that the coding states are the lowest energy states, their probability density being located at the bottom of the potential wells.

This has the effect that the GKP coding states are the lowest energy states in an interaction representation lowering the pulsation of the target mode to a pulsation lower than a third of the Josephson energy divided by the reduced Planck constant.

In this embodiment, in order to make it possible to stabilise the qubit, that is to say in order to bring an excited state of the GKP code back to a coding state, therefore of low energy, the circuit comprises a transmission line 4 that couples the circuit 2 with an environment of which the product of the Boltzmann constant by the effective temperature, in the interaction representation, is lower than the Josephson energy in this representation.

Consequently, the high energy states tend to relax by losing the energy through the transmission line 4 (as represented by the arrow in FIG. 7), so that in the event of excitation of the resonator, it naturally reverts to its low energy coding state as is apparent in FIG. 10, wherein the lines represent the various GKP Hamiltonian states depending on their energy level.

The above corresponds to an infinite-size GKP code. In the case of a finite-size GKP code, the duration between the pulses within the pulse train may be increased or reduced by a low quantity, typically lower than

$$\frac{4 {π}^{2} E}{5 {hw}^{2}}$$

where E is the amplitude of the modulation of the effective potential (V(q) and V(p)), h is the Planck constant.

This embodiment is particularly advantageous when the perturbations limiting the coherence of the qubit are Hamiltonian.

FIG. 11 represents a second embodiment of the quantum circuit 2 wherein the circuit 2 further comprises a measurement member 10 and a feedback member 12 disposed between the environment 4 and the linear passive circuit portion 6.

The pulsations wi are chosen here to correspond to a pulsation of one of the resonant modes of the Foster's decomposition across the terminals of the Josephson junction element 8 of the linear passive circuit portion 6 different from the pulsation w of the resonant mode of which the impedance is higher than or equal to 13 kohm, the pulsations wi being distinct from one another.

The measurement member 10 is homodyne linear of the resonant modes corresponding to the respective pulsations wi, arranged to measure the displacements of the resonant modes of pulsation wi in a direction of their respective phase plane determined by the phase of the sinusoidal carrier of pulsation wi, and makes it possible to measure the modular operators, that is to say measure the GKP error syndromes, without risk of error propagation, namely that the decoherence or dissipation affecting the ancillary mode does not risk inducing logic errors on the GKP qubit. The measurement member 10 may for example be implemented by a Josephson junction parametric amplifier operating close to the quantum limit.

The feedback member 12 is arranged to displace the state of the resonant mode exhibiting an impedance Z higher than 13 kohm in a direction of its phase plane determined by the phase of the pulse train corresponding to the pulsation wi at the phase reference of said resonant exhibiting an impedance Z higher than 13 kohm, proportionally to a measurement received by the measurement member 10. The feedback member 12 may be implemented by the application of a microwave to the pulsation w of which the phase and the amplitude are proportional to the result of the measurement.

Thus, as is apparent in FIG. 12, the GKP states are displaced by the feedback member 12 according to a vector of the phase plane of which the coordinates are proportional to the error syndromes s1 and s2 measured by the measurement member 10. The circuit 2 may also be arranged to have more than two error measurement syndromes.

This description corresponds to an implementation for an infinite-size GKP code. In the case of a finite-size GKP code, it would be possible to alternate the measurement of the modular operators with a linear feedback (as described above), with a low linear measurement (homodyne) with a low modular feedback.

Alternatively, the Applicant discovered that the pulse trains may be activated one after another by being modulated by the same sinusoidal carrier of pulsation wi, so that a pulse train ends before the activation of the following train, each train comprising a number of pulses between 10 and 10\hat{ }8.

The Applicant also discovered a third embodiment wherein the stabilisation is performed by dissipation.

Indeed, the stabilisation may be rendered autonomous with a simple dissipation on ancillary modes. A doubly modular dissipation of the target resonator is then obtained. More precisely, the circuit 2 of FIG. 13 makes it possible to stabilise the GKP logic qubit dissipatively by way of modular operators.

In the embodiment of FIG. 13, the Josephson junction element 8 comprises two Josephson junctions 44 parallel with one another, and its energy profile is modulated with sinusoidal carriers of which the pulsations wi are chosen in a similar way to that of the embodiment of FIGS. 11 and 12.

The linear passive circuit portion 6 is further arranged so that the resonant modes of pulsation wi dissipate their respective excitations into an environment of which the product of the temperature by the Boltzmann constant is lower than the product of the pulsation wi by the reduced Planck constant and according to a rate higher than √(w/4*Zᵢ/(6.5 kohm))*eᵢ where Zi is the impedance of the mode of pulsation wi across the terminals of the elements of said Josephson junction element and ei is the average Josephson energy integrated over the duration of a pulse.

As represented in FIG. 14, for the implementation adapted to a finite-size GKP code, each pulse is preceded by a pre-pulse and is followed by a post-pulse, the pre-pulse and the post-pulse (in dashed lines) being modulated by a quadrature sinusoidal carrier with the carrier of the pulse and being offset in relation to the pulse of a respective duration δ lower than 1/(5w) and having an opposite amplitude and of absolute value lower than 1/(3δw).

Preferably, the Josephson junction element 8 is coupled with four ancillary dissipative modes in order to perform a Lindblad dynamic with four dissipators. Nevertheless, it would be possible to perform a Lindblad dynamic with two dissipators, or even six dissipators.

Alternatively, the Applicant discovered that the pulse trains may be activated one after another by being modulated by the same sinusoidal carrier of pulsation wi, so that a pulse train ends before the activation of the following train, each train comprising a number of pulses between 10 and 10\hat{ }8.

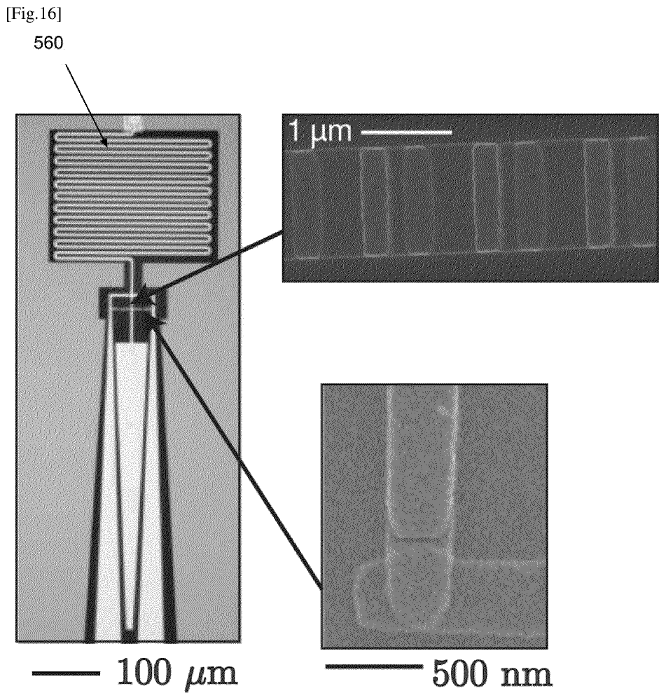

FIG. 16 represents a photograph view from above of an actual implementation of a circuit according to FIG. 13. This photograph was obtained by optical microscopy (left photograph) and by scanning electron microscopy (right photograph).

This figure comprises a plurality of enlargements making it possible to see the embodiment of the various elements better. Thus, it is possible to see an inductance 560 produced by a long track used to adjust the impedance of the ancillary modes exhibited at the Josephson junction element, as well as the tracks for the control signals. These enlargements also make it possible to better assess the orders of magnitudes, the Josephson junctions having a dimension in the order of 500 nm, the ATS a dimension in the order of 100 μm, and the tracks for the control signals a dimension in the order of the millimetre.

The circuit of FIG. 13 may be implemented by means of an ATS (Asymmetrically Threaded SQUID) circuit. The ATS circuit comprises a symmetrical SQUID that is short-circuited in its centre by a high inductance, which forms two loops.

Thus the ATS implements an LC oscillator added with a Josephson energy of controllable amplitude and phase. The common mode of the ring of the ATS circuit may have an impedance Z equal to 13 kohm and a resonance frequency in the RF range for a sufficiently high inductance in the central arm of the circuit. Distributed modes of low impedance, of adapted symmetry, and connected to the ring, may be used as ancillary modes. In the Foster's first-form representation, the capacities have values in the order of 10 fF, and the inductances have a value in the order of 1 to 10 μH.

Using an ATS instead of a SQUID is advantageous in the case of a Lindblad dynamic with four dissipators. Indeed, the control of the phase of each modular operator implemented thanks to the Josephson junction element is important in this case, two of the dissipators being associated with a cosine, and the other two being associated with a sine.

This embodiment is particularly advantageous because the ATS circuit was implemented in a practical way by the Applicant, which controls its manufacturing particularly well.

Advantageously, the impedance of the target mode as exhibited at the Josephson junction element 8 may be adjusted, which makes it possible to produce a universal set of Clifford gates. This adjustment may be performed by introducing an adjustable coupler between the linear passive circuit portion 6 and the Josephson junction element 8. This adjustable coupler may be produced in a manner known by the person skilled in the art, for example in the context of superconducting circuits (or “QED circuit”).

Thus, according to a first alternative embodiment, the impedance of the target resonant mode is equal to 13 kohm, which defines a square a GKP code. In this case, by slightly varying the duration between two pulses within each train, it is possible to progressively pivot the GKP state grid until an angle of rotation π/2 is obtained. Thus, a Hadamard gate is obtained.

In another alternative embodiment, the impedance of the target resonant mode is equal to 15 kohm, which defines a hexagonal GKP code. In this case, by slightly varying the duration between two pulses within each train, it is possible to progressively pivot the GKP state grid until an angle of rotation of π/3 of the GKP state grid is obtained. Thus, a gate of circular permutation of the three axes of the Bloch sphere of the logic qubit (X=>Y=>Z=>X . . . ) is obtained.

When two circuits exhibit an adjustable impedance and their linear passive circuit portions 6 are respectively connected to the Josephson junction element 8 of the other circuit by an adjustable coupler, it becomes possible to implement a CNOT gate.

In yet another alternative embodiment, the adjustable impedance may be used to produce a protected initialisation or protected read circuit of the logic qubit. In this case, the superconducting microwave quantum circuit comprises two Josephson junction elements 8. At least one Josephson junction element 8 is connected to the linear passive circuit portion 6 such that the impedance of the target mode that is exhibited thereto is adjustable. The area of the mesh of the GKP code is then reduced by a factor 2, and the energy of each Josephson junction element is controlled depending on the impedance of the target mode that is exhibited thereto. Advantageously, for a square GKP code, one of the target modes will have an impedance of 13 kohm, whereas the other an impedance of 6.5 kohm.

Although the present disclosure has been described with reference to one or more examples, workers skilled in the art will recognize that changes may be made in form and detail without departing from the scope of the disclosure and/or the appended claims.

1. A superconducting microwave quantum circuit comprising:
a controllable-energy Josephson junction element connected to a linear passive circuit portion exhibiting a plurality of resonant modes, of which a Foster's first-form decomposition across terminals of the Josephson junction element comprises a target resonant mode exhibiting an impedance Z higher than 13 kohm and a pulsation w,
an energy of said Josephson junction element being controllable and modulated by at least two respective pulse trains within which the pulses are separated by a duration 2π/w and have a width of less than one tenth of said duration, an amplitude of the pulses within each respective pulse train being modulated by a respective sinusoidal carrier and the pulse trains being respectively offset pairwise by a duration Δt such that |sin(w*At)| equals 13 kohm/Z, so that a resonant mode of pulsation w is stabilised in one of two GKP (Gottesman-Kitaev-Preskill) states encoding a qubit.

2. The superconducting microwave quantum circuit according to claim 1, wherein a pulsation wi of the sinusoidal carrier of each respective pulse train is zero, so that the GKP coding states are the lowest energy states in an interaction representation lowering the pulsation of the target resonant mode to a pulsation lower than a fifth of the amplitude of the effective modular potential generated for the target resonant mode divided by the reduced Planck constant, said lowest energy states being stabilised by coupling with an environment of which a product of the Boltzmann constant by an effective temperature is lower than the Josephson energy in this representation.

3. The superconducting microwave quantum circuit according to claim 1, wherein a pulsation wi of the sinusoidal carrier of each respective pulse train is a pulsation of a resonant mode of the Foster's decomposition across the terminals of the Josephson junction element of the linear passive circuit portion different from the pulsation w, the superconducting microwave quantum circuit further comprising a homodyne linear measurement member of the resonant modes corresponding to the respective pulsations wi, arranged to measure displacements of the resonant modes of pulsation wi in a direction of their respective phase plane determined by the phase of the sinusoidal carrier of pulsation wi, and a feedback member arranged to displace a state of the target resonant mode in a direction of a phase plane of the target resonant mode determined by a phase of the pulse train corresponding to the pulsation wi in relation to a phase reference of said target resonant mode, proportionally to a measurement received from the measurement member.

4. The superconducting microwave quantum circuit according to claim 1, wherein a pulsation wi of the carrier of each respective pulse train is a pulsation of one of the resonant modes of the Foster's first-form decomposition across the terminals of the Josephson junction element of the linear passive circuit portion different from the pulsation w, the linear passive circuit portion being arranged so that said resonant modes of pulsation wi dissipate their respective excitations into an environment of which a product of temperature by the Boltzmann constant is lower than a product of the pulsation wi by the reduced Planck constant and according to a rate higher than
$$\sqrt{\frac{w}{4} * \frac{{Z}_{i}}{6.5 kohm}} * {e}_{i}$$
where Zi is an impedance of the mode of pulsation wi across the terminals of the elements of said Josephson junction element and ei is the average Josephson energy integrated over the duration of a pulse, each pulse being preceded by a pre-pulse and followed by a post-pulse, the pre-pulse and the post-pulse being modulated by a quadrature sinusoidal carrier with the carrier of the pulse and being offset in relation to the pulse of a respective duration δ lower than 1/(5w) and having an opposite amplitude and of absolute value lower than 1/(3δw).

5. The superconducting microwave quantum circuit according to claim 1, wherein the respective pulse trains are activated in time windows that overlap, and wherein the pulsations of the sinusoidal carriers that modulate their respective amplitudes are distinct.

6. The superconducting microwave quantum circuit according to claim 1, wherein the respective pulse trains are activated one after another and are modulated by the same sinusoidal carrier of pulsation wi, so that a pulse train ends before the activation of a following train, each train comprising a number of pulses between 10 and 10\hat{ }8.

7. The superconducting microwave quantum circuit according to claim 1, wherein the Josephson junction element has a controllable phase making it possible to modify a position of a state grid of the GKP.

8. The superconducting microwave quantum circuit according to claim 1, wherein the impedance of the target resonant mode is adjustable, and wherein the offset between the respective pulse trains may be adapted to make it possible to modify a shape of a mesh of a state grid of the GKP.

9. The superconducting microwave quantum circuit according to claim 8 wherein the impedance of the target resonant mode is equal to 13 kohm, wherein the pulsation of the target resonant mode is modified in order to perform a rotation of η/2 of the GKP state grid, and wherein the duration between the pulses within the same train is modified in a manner adapted to this modified pulsation.

10. The superconducting microwave quantum circuit according to claim 8 wherein the impedance of the target resonant mode is equal to 15 kohm, wherein the pulsation of the target resonant mode is modified in order to perform a rotation of π/3 of the GKP state grid, and wherein the duration between the pulses within the same train is modified in a manner adapted to this modified pulsation.

11. The superconducting microwave quantum circuit according to claim 8 comprising two controllable-energy Josephson junction elements, each connected to said linear passive circuit portion such that the impedance of the target resonant mode exhibited at at least one of two Josephson junction elements is adjustable, the energy of each Josephson junction element being controllable and modulated depending on each respective impedance of the target resonant mode.

12. A superconducting microwave quantum circuit, comprising two circuits of which one at least is according to claim 8 and interconnected so as to define a logic gate.

13. The superconducting microwave quantum circuit according to claim 12, wherein said two circuits are according to claim 8, the linear passive circuit portion of each circuit being connected to the Josephson junction element of the other circuit by an adjustable coupler so as to control the impedance of the target resonant mode of each circuit exhibited at the Josephson junction element of the other circuit.
